(19) United States
(12) Patent Application Publication
(10) Pub. No.: US 2024/0414880 A1
(43) Pub. Date: Dec. 12, 2024

(54) COOLING FIN OF A COOLER, THROUGH WHICH FLUID CAN FLOW, FOR COOLING POWER ELECTRONICS

(71) Applicant: Robert Bosch GmbH, Stuttgart (DE)

(72) Inventors: Marco Lorenz, Ditzingen (DE); Max Florian Beck, Vaihingen An Der Enz (DE); Wolfram Kienle, Magstadt (DE)

(21) Appl. No.: 18/700,998

(22) PCT Filed: Sep. 28, 2022
(86) PCT No.: PCT/EP2022/076984

§ 371 Date: Apr. 12, 2024

(30) Foreign Application Priority Data
Oct. 13, 2021 (DE) 10 2021 211 544.6

(51) Int. Cl. H05K 7/20

(52) U.S. Cl. CPC H05K 7/20263; H05K 7/20927

(57) ABSTRACT

The present invention relates to a cooling fin (1) of a cooler (100), through which fluid can flow, for cooling power electronics (200). The cooling fin (1) comprises a profile (10) periodically repeating in a repeating direction (501), wherein the repeating direction (501) is perpendicular to an extending direction (500) of the profile (10). The invention also relates to a cooler (100), through which fluid can flow, for cooling power electronics (200), said cooler comprising a cooling fin (1) of said type, and to a power electronics assembly (1000), comprising power electronics (200) and a cooler (100) of said type, through which fluid can flow.

### BACKGROUND

The present invention relates to a cooling fin of a cooler, through which fluid can flow, for cooling power electronics. In particular, the invention relates to a cooling fin which enables optimized cooling of power electronics. The invention further relates to a cooler, through which fluid can flow, and which comprises a cooling fin, in particular exactly one such cooling fin, and to an arrangement which comprises power electronics and a cooler of this type.

Power semiconductors in power electronics assemblies carry high electrical currents. Together with switching losses, the resulting conduction losses are the cause of high heat dissipation, which must be dissipated over a very small area. The maximum permissible semiconductor temperature is thereby critical to failure, for which reason minimizing the thermal resistance between the semiconductor and coolant is of central importance. For efficient cooling, the power substrates are applied to coolers through which fluid can flow. These coolers are made of aluminum, AlSiC, or copper alloys. Pins or fins are arranged inside the cooler to increase the heat transfer surface and intensify the heat transfer. In order to achieve a low thermal resistance between a power substrate, in particular an AMB/DBC power substrate (AMB: active metal braze; DBC: direct copper bonding), and the cooler, the power substrate is joined to the cooler by means of a soft soldering process or, optionally, a sintering process. For this purpose, these coolers can be surface-coated with materials suitable for a soft soldering process or a sintering process. In automotive engineering, aluminum coolers, also AlSiC or copper coolers, which consist of a plurality of components that are joined in particular by a brazing process, are frequently known.

Often, fins made of punched sheet metal are used in coolers through which fluid can flow. Existing fin geometries do not meet the requirements of a cooler, through which fluid can flow, for cooling power electronics. The thermal performance is essentially determined by the heat transfer between the fluid and the fin surface, the fin surface and the fin efficiency.

### SUMMARY

The advantage of the cooling fin of a cooler, through which fluid can flow, for cooling power electronics assembly according to the invention is that it enables optimum cooling of the power electronics assembly. In particular, the cooling fin can achieve an advantageous ratio between the thermal performance of the cooling fin and the pressure loss caused in the cooler. The cooling fin according to the invention is therefore particularly suitable for use in coolers, through which fluid can flow for high-power electronic applications. This is achieved by the cooling fin of a cooler, through which fluid can flow in order to cool power electronics, comprising a profile which periodically repeats in a repeating direction, the repeating direction being perpendicular to an extending direction of the profile. It should be noted that, in the context of the invention, the term “profile” refers in particular to an element, especially a sheet-shaped element, whose cross-section is constant over its entire length. The direction of the length of the profile can be referred to as the longitudinal direction of the profile and corresponds to the extending direction of the profile. In particular, the extending direction of the profile corresponds to a flow direction.

The flow direction corresponds in particular to a main flow direction of a fluid used as a coolant, which flows through at least one passage channel formed at least by the repeating profile. In particular, the main flow direction is in this case the direction in which the fluid mainly flows, i.e., the direction in which a velocity component of the fluid is greater than a velocity component of the fluid in a direction parallel to the repeating direction. The main flow direction preferably corresponds to a direction in which the fluid enters the cooler, through which fluid can flow. The repeating direction corresponds in particular to a width direction of the cooler. The cooling fin serves as a surface-enlarging, flow-guiding and heat-transfer-enhancing structure, whereby increased heat dissipation and thus also improved cooling of power electronics can be achieved. The cooling fin can preferably be produced in a punching and/or roll forming process for ideal surface utilization with maximum fin efficiency. However, it is also possible for the cooling fin to be produced by an extrusion process for the same purpose, depending on the shape.

Preferably, the profile is repeated an integer or non-integer number of times. In other words, for an integer number of repetitions of the profile, the cooling fin corresponds to an integer multiple of the periodically repeating profile. On the other hand, a non-integer number of repetitions means that the cooling fin is not an integer multiple of the periodically repeating profile. How many times the profile repeats advantageously depends on a width of the power electronics assembly, in particular a power electronics unit, which is to be cooled by a cooler comprising the cooling fin.

Preferably, the cooling fin comprises at least one passage channel, in particular a plurality of passage channels. The at least one passage channel is at least partially formed by the repeating profile. The fluid used as a coolant flows through the at least one passage channel, to which heat generated by the power electronics assembly is transferred via the cooling fin and through which it is dissipated.

According to a first advantageous embodiment of the invention, the periodically repeating profile is a corrugated profile. In particular, the cooling fin is formed by a periodically repeating corrugated profile. As a result, a large surface area of the cooling fin and thus an improved cooling performance can be achieved without the cooling fin becoming too large in the repeating direction. In this embodiment, the cooling fin can preferably be produced by means of a punching and/or roll forming process.

It should be noted that the term “corrugated profile” refers to any profile that features a cross-section in the shape of a shaft, whereby the shaft can have any shape as long as it includes a region having a maximum height and a region having a minimum height. In particular, this means that the shaft need not necessarily be designed as a curve, but can also comprise only rectilinear sections or a combination of curved and rectilinear sections. In other words, within the scope of the invention, the corrugation profile of the cooling fin repeats in the repeating direction and extends in the extending direction. It is understood that the periodically repeating corrugated profile forms a larger corrugated profile in the repeating direction, which features a cross-section which is formed by the individual cross-sections of the repeating corrugated profile specified hereinabove. Therefore, within the scope of the invention, the cooling fin can in particular comprise a cooling fin corrugated profile which corresponds to the larger corrugated profile specified hereinabove.

Preferably, the cooling fin is meander-shaped. In other words, a cross-section of the cooling fin preferably features a meandering shape. In the context of the invention, a “meander” is in particular a shaft comprising rectilinear or substantially rectilinear sections situated perpendicular or substantially perpendicular to one another. In other words, the sections are arranged relative to each other such that rectangular or substantially rectangular deflections are formed between adjacent or directly interconnected sections. The expression “substantially perpendicular” means in particular a deviation of at most 10 degrees, preferably at most 8 degrees, from the perpendicular position.

The repeating corrugated profile or a repetition of the corrugated profile preferably in this case comprises a first bar, a second bar, a third bar, and a fourth bar. The first bar and second bar can be referred to as legs. The first bar and second bar extend in a height direction which is perpendicular to the repeating direction, whereby the third bar and the fourth bar extend parallel to the repeating direction. The first bar and the second bar are preferably connected to each other via the third bar, whereby the fourth bar is preferably connected to the second bar. Passage channels are in this case advantageously formed between adjacent bars. In particular, passage channels are defined alternately by a first bar, an adjacent second bar and an adjacent third bar as well as by a first bar, an adjacent second bar and an adjacent fourth bar.

It is understood that, due to the repetition of the repeating corrugated profile, the first bar and/or the second bar and/or the third bar and/or the fourth bar also repeat/repeat in an advantageous manner. In other words, the cooling fin can comprise a plurality of first bars and/or second bars and/or third bars, and/or fourth bars.

It should be noted that a region of the corrugated profile having a maximum height comprises in particular the third bar. Correspondingly, a region of the corrugated profile having a minimum height comprises in particular the fourth bar.

The third bar advantageously faces the power electronics assembly, whereby the fourth bar faces away from the power electronics assembly.

A first bar, which is connected to a third bar, can preferably merge into the third bar via a rounding radius (inner and outer radii). A third bar, which is connected to a second bar, can preferably merge into the second bar via a rounding radius (inner and outer radii). These rounding radii can preferably be the same and collectively referred to as the first rounding radius.

A second bar, which is connected to a fourth bar, can preferably merge into the fourth bar via a rounding radius (inner and outer radii). A fourth bar, which is connected to a first bar, can preferably merge into the fourth bar via a rounding radius (inner and outer radii). These rounding radii can preferably be the same and are collectively referred to as the second rounding radius.

Advantageously, the second rounding radius is larger than the first rounding radius, in particular twice as large as the first rounding radius. Advantageously, the first rounding radius is the same size as a profile thickness of the cooling fin.

When the profile is designed as a corrugated profile, the division of the cooling fin can preferably measure between 1.8 mm and 2.5 mm, preferably between 1.9 mm and 2.1 mm, in particular 2 mm. The division of the cooling fin corresponds to the period at which the periodically repeating corrugated profile is repeated to form the cooling fin.

According to a second advantageous embodiment of the invention, the periodically repeating profile is a cross-shaped profile. This embodiment of the cooling fin is advantageous, since the cross-shaped profile is firstly easy to manufacture and secondly comprises a large surface area for transferring heat to the fluid used as coolant. In particular, the cooling fin is formed by a periodically repeating cross-shaped profile. The cross-shaped profile preferably comprises a first bar, a second bar and a third bar, whereby the first bar and the second bar are each situated at a perpendicular angle to the third bar and protrude from the third bar. It is understood that the bars are arranged relative to each other such that the profile features the shape of a cross. Advantageously, the third bar extends in the repeating direction of the repeating profile. The at least one passage channel described hereinabove preferably comprises in this case at least one passage channel between adjacent first bars and a passage channel between adjacent second bars. In particular, at least one passage channel is defined by adjacent first bars and adjacent third bars, whereby at least one passage channel is defined by adjacent second bars and adjacent third bars. Preferably, the cooling fin according to this embodiment is produced by means of an extrusion process.

It is understood that, due to the repetition of the repeating cross-shaped profile, the first bar, and/or the second bar, and/or the third bar(s) also repeat in an advantageous manner. In other words, the cooling fin can comprise a plurality of first bars and/or second bars and/or third bars.

Preferably, the cooling fin can further comprise a fourth bar extending parallel to the third bar and connected to an end region of each first bar or each second bar. Advantageously, the fourth bar extends in the extending direction of the profile.

Alternatively, the cooling fin can further preferably comprise a fourth bar and a fifth bar extending parallel to the third bar. In this case, the fourth bar is connected to an end region of each first bar, whereby the fifth bar is connected to an end region of each second bar. Advantageously, the fourth bar and the fifth bar extend in the extending direction of the profile.

Advantageously, the fourth bar and/or the fifth bar extend(s) in the repeating direction of the repeating profile. Advantageously, the aforementioned at least one passage channel comprises at least one passage channel between adjacent first bars and at least one passage channel between adjacent second bars.

According to an advantageous variant of the second embodiment of the invention, a dimension of the first bar in the repeating direction can be the same as a dimension of the second bar in the repeating direction. The cooling fin can therefore be easily manufactured.

According to an alternative advantageous variant of the second embodiment of the invention, a dimension of the first bar in the repeating direction can be larger than a dimension of the second bar in the repeating direction. Heat dissipation through the cooling fin can therefore be further improved. In this case, it is advantageous if the first bar of the cross-shaped profile is arranged to face the power electronics assembly, whereby the second bar of the cross-shaped profile is arranged to face away from the power electronics. In other words, in this embodiment, the first bar is arranged to be closer to the power electronics assembly than the second bar. Due to the different dimensions of the first bar and the second bar, the flow, in particular the flow velocity, of the fluid used as coolant can be influenced such that a desired heat transfer coefficient of the fluid is achieved.

The dimension of the first bar or the second bar in the repeating direction corresponds in particular to a material thickness of the first bar or the second bar.

According to a third advantageous embodiment of the invention, the periodically repeating profile is a V-shaped profile having a first bar and a second bar. The cooling fin can in this case preferably further comprise a third bar, whereby the third bar extends in the repeating direction and is arranged such that a triangular passage channel is formed for each repetition of the profile by the first bar, the second bar, and the third bar. The third bar extends advantageously in the extending direction of the profile. Alternatively, the cooling fin can preferably further comprise a third bar and a fourth bar, whereby the third bar and the fourth bar extend in the repeating direction and are arranged such that triangular passage channels are formed in the cooling fin. The third bar and the fourth bar extend advantageously in the extending direction of the profile. Preferably, the cooling fin according to the third advantageous embodiment is produced by means of an extrusion process.

It is understood that, due to the repetition of the repeating V-shaped profile, the first bar and/or the second bar also repeat in an advantageous manner. In other words, the cooling fin can comprise a plurality of first bars and/or second bars.

The shapes of the cooling fins according to the advantageous embodiments of the invention described above can in particular enable an advantageous ratio of a thermal performance to a pressure loss in the cooler caused by the cooling fin.

Particularly preferably, a height of the cooling fin can measure between 5 mm and 8 mm, preferably between 5.9 mm and 6.1 mm. The height is advantageously measured in a height direction that is perpendicular to the repeating direction and extending direction of the profile.

Particularly preferably, the material thickness of the cooling fin can measure between 0.3 mm and 0.6 mm, preferably between 0.35 mm and 0.45 mm. In the cooling fin according to the first embodiment described above, the material thickness of the cooling fin corresponds in particular to a profile thickness of the repeating corrugated profile. In the cooling fin according to the second embodiment described above, the material thickness of the cooling fin comprises in particular a profile thickness of the repeating cross-shaped profile and in particular also a material thickness of the fourth bar and/or the fifth bar. In the cooling fin according to the third embodiment described above, the material thickness of the cooling fin comprises in particular a profile thickness of the V-shaped profile and/or a material thickness of the fourth bar and/or the fifth bar.

Particularly preferably, a clear dimension between adjacent bars of the cooling fin in the repeating direction can measure between 0.6 mm and 1.2 mm, preferably between 0.85 mm and 0.95 mm. In the first advantageous embodiment, the clear dimension between adjacent bars is in particular a clear dimension between a first bar and an adjacent second bar. In the cooling fin according to the second advantageous embodiment described above, the clear dimension between adjacent bars comprises in particular a clear dimension between adjacent first bars and/or a clear dimension between adjacent second bars. In the cooling fin according to the third advantageous embodiment described above, the clear dimension between adjacent bars corresponds in particular to a maximum clear dimension between a first bar and an adjacent second bar.

In an advantageous manner, the cooling fin is designed as monobloc/monolithic.

The cooling fin is preferably made of a material and/or coated with a material that features a coefficient of thermal conductivity greater than 150 W/(m-K). Advantageously, the cooling fin can be made of aluminum or coated with aluminum or nickel.

The present invention further relates to a cooler, through which fluid can flow, for cooling power electronics, which comprises a cooling fin as described above.

The cooler, through which fluid can flow, preferably comprises exactly one cooling fin as described above and a cooling channel. The cooling fin is in this case arranged in the cooling channel. A length of the cooling fin in the extending direction of the repeating profile is equal to a dimension of the cooling channel in the extending direction of the repeating profile.

Preferably, the cooler, through which fluid can flow, comprises a housing. The housing can preferably be made of at least two metal parts, in particular aluminum parts, which are connected to each other and define the cooling channel. The cooling channel in this case corresponds in particular to an interior of the housing.

Further preferably, an inlet and an outlet for a fluid used as a coolant are arranged directly on the housing.

Preferably, one region of the cooling fin corresponds to at least part of the housing of the cooler. In other words, a region of the cooling fin is formed at least as part of the housing of the cooler. In an advantageous manner, the fourth bar an—depending on the design of the cooling fin—in particular also the fifth bar in the cooling fin according to the advantageous fourth embodiment described above each correspond to at least a part of the housing. In particular, the fourth bar can partially or completely correspond to a metal part of the at least two metal parts of the housing. If a fourth bar and a fifth bar are provided in the cooling fin, the fourth bar can partially or completely correspond to a first metal part of the at least two metal parts of the housing and the fifth bar can correspond to a second metal part of the at least two metal parts of the housing.

The present invention further relates to a power electronics assembly comprising a cooler, through which fluid can flow, as described hereinabove, and power electronics. The power electronics assembly is in this case arranged on the cooler. As a result, the power electronics assembly can be cooled by means of the cooler. In particular, the power electronics assembly is fixed to the cooler.

Preferably, the power electronics can comprise (exactly) one power electronics unit or a plurality of power electronics units. The power electronics units can be arranged on one or both sides of the cooler, through which fluid can flow, or its housing. In other words, the cooler, through which fluid can flow, can be equipped with power electronics units on one or both sides.

The power electronics can preferably comprise at least a first power electronics unit and a second power electronics unit. In the main flow direction of the fluid used as coolant, the first power electronics unit is preferably arranged upstream of the second power electronics unit. Furthermore, the power electronics can preferably comprise a third power electronics unit. Preferably, the third power electronics unit is in this case arranged downstream of the second power electronics unit in the main flow direction of the fluid.

In the context of the invention, a power electronics unit can in particular also be referred to as a power module. The power electronics unit preferably comprises a printed circuit board and/or conductor tracks and/or one or a plurality of power semiconductors.

### BRIEF DESCRIPTION OF THE DRAWINGS

Hereinafter, exemplary embodiments of the invention are described in detail with reference to the accompanying drawings, whereby identical or functionally identical components are indicated by the same reference character. In the drawings:

FIG. 1 is a schematic simplified sectional view of a power electronics assembly according to the invention comprising power electronics and a cooler, through which fluid can flow, and which comprises a cooling fin, according to a first exemplary embodiment of the invention,

FIG. 2 is a schematic perspective view of the cooling fin according to the first exemplary embodiment of the invention,

FIG. 3 is a schematic front view of a cooling fin according to a second exemplary embodiment of the invention,

FIG. 4 is a schematic front view of a cooling fin according to a third exemplary embodiment of the invention,

FIG. 5 is a schematic front view of a cooling fin according to a fourth exemplary embodiment of the invention,

FIG. 6 is a schematic front view of a cooling fin according to a fifth exemplary embodiment of the invention,

FIG. 7 is a schematic front view of a cooling fin according to a sixth exemplary embodiment of the invention,

FIG. 8 is a schematic simplified sectional view of a power electronics assembly according to a seventh exemplary embodiment of the present invention,

FIG. 9 is a schematic simplified sectional view of a power electronics assembly according to an eighth exemplary embodiment of the present invention, and

FIG. 10 is a schematic simplified sectional view of a power electronics assembly according to a ninth exemplary embodiment of the present invention.

### DETAILED DESCRIPTION

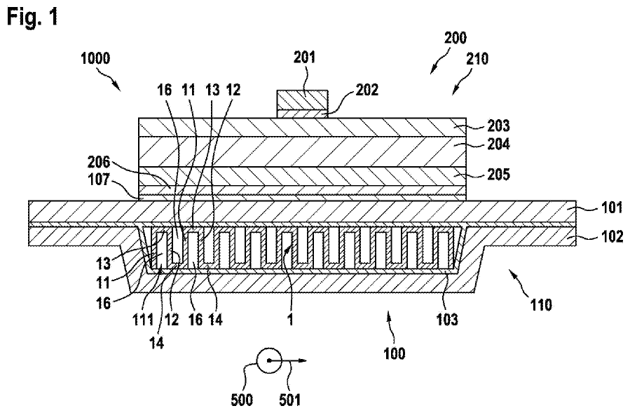

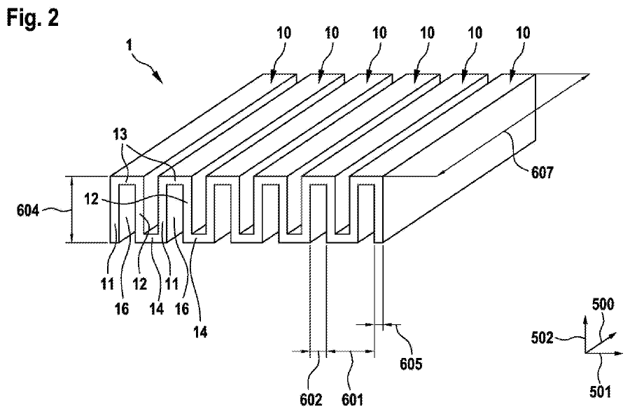

Referring to FIGS. 1 and 2, a power electronics assembly 1000 according to the invention comprising power electronics 200 and a cooler 100 according to a first exemplary embodiment of the invention is described below.

As shown in FIG. 1, the power electronics 200 comprises a power electronics unit 210, which can also be referred to as a power module. The power electronics unit 210 comprises a printed circuit board 204, conductor tracks 203, 205 and power semiconductors 201. The conductor tracks 203, 205 are designed in particular as copper conductor tracks, whereby the printed circuit board 204 is preferably made of ceramic.

The power semiconductors 201 are applied to the trace 203 by a layer 202. In particular, the layer 202 is in this case designed as a solder or sintered layer.

The conductor tracks 203, 205 together with the printed circuit board 204 form a power substrate. The power substrate is joined to the cooler 100, in particular to a first metal part 101 of a housing 110 of the cooler 100, by means of a layer 206 produced by a soft soldering process or a sintering process, which is thus correspondingly a soft soldering layer or sintering layer.

The housing 110 of the cooler 100 further comprises a second metal part 102, which is connected to the first metal part 101 by means of a layer 103, which is in particular designed as a brazing solder layer. Both the first metal part 101 and the second metal part 102 are preferably aluminum parts.

FIG. 1 also shows that the first metal part 101 is an upper part and the second metal part 102 is a lower part of the housing 110. The first metal part 101 faces the power electronics unit 210, whereby the second metal part 102 faces away from the power electronics unit 210. Furthermore, in this exemplary embodiment, the first metal part 101 is plate-shaped, whereby the second metal part 102 comprises a plate-shaped region and a trapezoidal region in cross-section. However, it is also possible for the first metal part 101 and the second metal part 102 to feature other shapes. The second metal part 102 can advantageously be produced by a deep-drawing process.

A mediation layer 107 is advantageously located between the layer 206 and the cooler 100 (in particular the first metal part 101), which layer is firmly connected to the first metal part 101 and enables wetting of the layer 206. The mediation layer 107 is an optional feature of the power electronics assembly 1000 and can in particular be considered either as a separate part or as part of the housing 110 of the cooler 100.

The first metal part 101 and the second metal part 102, which form the housing 110 of the cooler 100 when joined together, define an interior space which serves as the cooling channel 111 of the cooler 100.

Exactly one cooling fin 1 is arranged in the cooling channel 111, which serves as a surface-enlarging, flow-guiding, and heat-transfer-enhancing structure for a fluid used as a coolant. The cooling fin 1 is advantageously joined to the first metal part 101 and second metal part 102 by means of the layer 103.

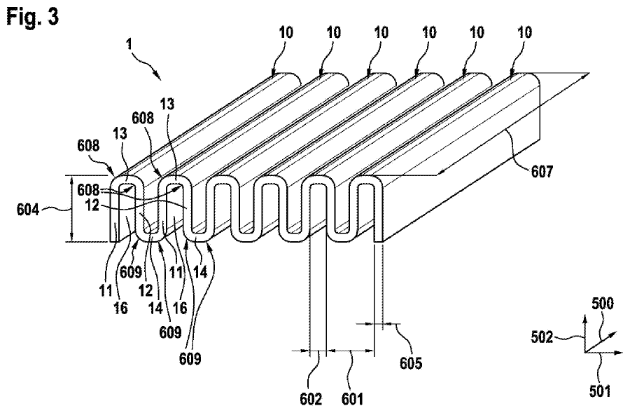

The cooling fin 1 is formed by a profile 10 periodically repeating in a repeating direction 501. The repeating direction 501 is perpendicular to an extending direction 500 of the profile 10 and corresponds in particular to a width direction of the cooler 100. The extending direction 500 is the direction in which the repeating profile 10 or the cooling fin 1 extends as a unit. The extending direction 500 corresponds in this case to a flow direction 500, in particular a main flow direction, of a fluid used as coolant when it flows through the cooling channel 111, in particular through passage channels 16 (FIGS. 1 and 3), which are formed by the repeating profile 10. The single cooling fin 1 extends in the extending direction 500 over an entire length of the cooling channel 111 of the cooler 100 in the extending direction 500. In other words, a length 607 of the cooling fin 1 is the same as the entire length of the cooling channel 111.

In this exemplary embodiment, the repeating corrugated profile 10 is a corrugated profile. In particular, the cooling fin 1 is meander-shaped. The cooling fin 1 is designed to be monobloc or monolithic and is preferably manufactured by means of a stamping process.

The repeating corrugated profile, or rather each repetition of the corrugated profile, comprises a first bar 11, a second bar 12, a third bar 13, and a fourth bar 14.

The first bar 11 and second bar 12 of the repeating corrugated profile extend in a height direction 502 that is perpendicular to the repeating direction 501 and extending direction 500, whereby the third bar 13 and fourth bar 14 extend parallel to the repeating direction 501. The cooling fin 1 therefore comprises a plurality of first bars 11, second bars 12, third bars 13, and fourth bars 14. A first bar 11 is connected to an adjacent second bar 12 via a third bar 13 or a fourth bar 14. A transition from one of the bars 11 to 14 to an adjacent bar is formed at a right angle (not rounded).

Passage channels 16 are in this case formed between adjacent bars 11, 12. A clear dimension 602 between adjacent bars 11, 12 in the repeating direction 501, which corresponds to the dimension of the corresponding passage channel 16 formed, measures between 0.6 mm and 1.2 mm, preferably between 0.85 mm and 0.95 mm.

A division 601 of the cooling fin 1 can measure between 1.8 mm and 2.5 mm, preferably between 1.9 mm and 2.1 mm. The division 601 of the cooling fin 1 in this case corresponds to the period at which the periodically repeating profile 10 is repeated to form the cooling fin 1.

A height 604 of the cooling fin 1 measures between 5 mm and 8 mm, preferably between 5.9 mm and 6.1 mm.

Furthermore, a material thickness 605 of the cooling fin 1 can measure between 0.3 mm and 0.6 mm, preferably between 0.35 mm and 0.45 mm. The material thickness 605 of the cooling fin 1 in this case corresponds to a profile thickness of the repeating corrugated profile or a material thickness of the bars 11 to 14.

By means of the cooling fin 1, heat generated during operation of the power electronics unit 210 can be efficiently transferred from the power electronics unit 210 first to the first metal part 101 and from there to a fluid flowing through the cooling fin 10 and dissipated. Furthermore, an optimum ratio between thermal performance and the pressure loss caused in the cooler 100 is achieved.

In order to achieve advantageous heat transfer and at the same time enable simple manufacture, the cooling fin 1 is advantageously made of aluminum. Alternatively, the cooling fin 1 can be provided with an aluminum layer. It is also possible that the cooling fin 1 is coated with nickel. However, it is also possible that other thermally conductive materials are used for the cooling fin 1 and/or the layer thereof, which in particular have a coefficient of thermal conductivity greater than 150 W/(m-K).

The cooler 100 can further preferably comprise coolant nozzles,
which can also be joined together by means of a hard solder in the manufacturing step of joining the two metal parts 101, 102.

FIG. 3 relates to a cooling fin 1 according to a second exemplary embodiment of the invention.

The structure of the cooling fin 1 according to the second exemplary embodiment is basically identical to the structure of the cooling fin 1 according to the first exemplary embodiment.

The only difference is the shape of the transitions between adjacent bars.

In particular, in the cooling fin 1 according to the second exemplary embodiment, the first bars 11, which are each connected to a third bar 13, merge into the corresponding third bar 13 via a first rounding radius (inner and outer radii). Furthermore, the third bars 13, which are each connected to a second bar 12, merge into the corresponding second bar 12 via the first rounding radius 608 (inner and outer radii). The second bars 12, which are each connected to a fourth bar 14, merge into the corresponding fourth bar 14 via a second rounding radius 609 (inner and outer radii). Furthermore, the fourth bars 14, which are each connected to a first bar 11, merge into the corresponding first bar 11 via the second rounding radius 609 (inner and outer radii).

The second rounding radius 609 is larger than the first rounding radius 608, in particular twice as large as the first rounding radius 608. In an advantageous manner, the first rounding radius 608 is the same size as the profile thickness 605 of the cooling fin 1.

The cooling fin 1 according to the second exemplary embodiment can replace the cooling fin 1 according to the first exemplary embodiment in the cooler 100 in FIG. 1. In this case, the cooling fin 1 is arranged in the cooling channel 111 of the cooler 100 such that the third bars 13 are closer to the power electronics unit 210 than the fourth bars 14.

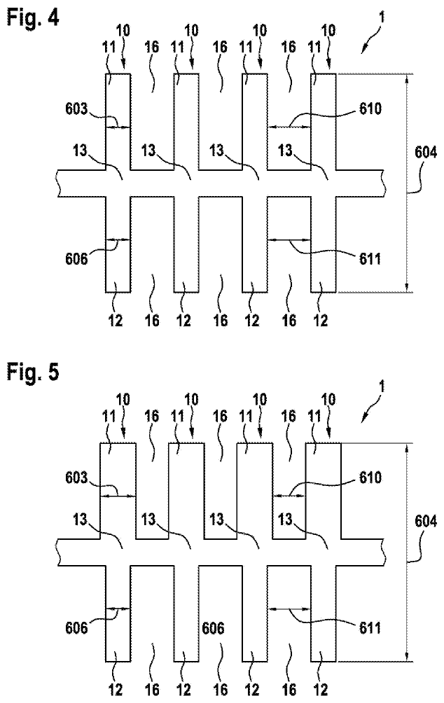

FIG. 4 refers to a cooling fin 1 according to a third exemplary embodiment of the invention.

The cooling fin 1 is in this case formed by a periodically repeating profile 10, which is a cross-shaped profile. Preferably, the cooling fin 1 is an extrusion product.

The cross-shaped profile comprises a first bar 11, a second bar 12 and a third bar 13. The first bar 11 and the second bar 12 are in this case each situated at a perpendicular angle to the third bar 30 and protrude from the third bar 13. The third bar 13 extends in the repeating direction 501 of the repeating profile 10. The cooling fin 1 therefore comprises a plurality of first bars 11, second bars 12, and third bars 13.

Passage channels 16 for the fluid used as coolant are formed between adjacent first bars 11, whereby further passage channels 16 for the fluid are formed between adjacent second bars 12.

A dimension (material thickness) 603 of the first bar 11 in the repeating direction 501 is equal to a dimension (material thickness) 606 of the second bar 12 in the repeating direction 501. Therefore, a clear dimension 610 between adjacent first bars 11 in the repeating direction 501 is also equal to a clear dimension 611 between adjacent second bars 12 in the repeating direction 501. In particular, the clear dimension 610 or 611 measures between 0.6 mm and 1.2 mm, preferably between 0.85 mm and 0.95 mm. Both the clear dimension 610 and the clear dimension 611 correspond to the dimension of the respective passage channel 16 formed in the repeating direction 501.

A height 604 of the cooling fin 1 measures between 5 mm and 8 mm, preferably between 5.9 mm and 6.1 mm.

FIG. 5 relates to a cooling fin 1 according to a fourth exemplary embodiment of the invention.

The cooling fin 1 according to the fourth exemplary embodiment of the invention differs from that according to the third exemplary embodiment in that the dimension (material thickness) 603 of the first bars 11 in the repeating direction 501 is greater than the dimension (material thickness) 606 of the second bars 12 in the repeating direction 501. Therefore, the clear dimension 610 between adjacent first bars 11 in the repeating direction 501 is also smaller than the clear dimension 611 between adjacent second bars 12 in the repeating direction 501.

The cooling fin 1 according to the third exemplary embodiment of the invention can be provided in the housing 110 of the cooler 100 in FIG. 1. In particular, the cooling fin 1 is then arranged in the cooling channel 111 such that the first bars 11 face the power electronics 200, whereby the second bars 12 face away from the power electronics 200.

FIG. 6 shows a cooling fin 1 according to a fifth exemplary embodiment of the present invention.

The cooling fin 1 according to the fifth exemplary embodiment differs from that according to the third exemplary embodiment in that the cooling fin 1 in this case additionally comprises a fourth bar 14 and a fifth bar 15, which extend parallel to the third bar 13. The fourth bar 14 and the fifth bar 15 therefore extend parallel to the repeating direction 501 and extend in the extending direction 500.

The fourth bar 14 is arranged at end regions 18 of the first bars 11 and is connected thereto. The fifth bar 15 is arranged at end regions 18 of the second bars 12 and is connected thereto.

Due to this design of the cooling fin 1, passage channels 16 for the fluid used as coolant are formed between adjacent first bars 11 and the fourth bar 14 and between adjacent second bars 12 and the fifth bar 15.

The cooling fin 1 according to the fifth exemplary embodiment of the invention can replace the cooling fin 1 according to the first exemplary embodiment. Furthermore, it is possible that the fourth bar 14 forms the first metal part 101 and the fifth bar 15 forms the second metal part 102 of the housing 100 in FIG. 1, in whole or in part.

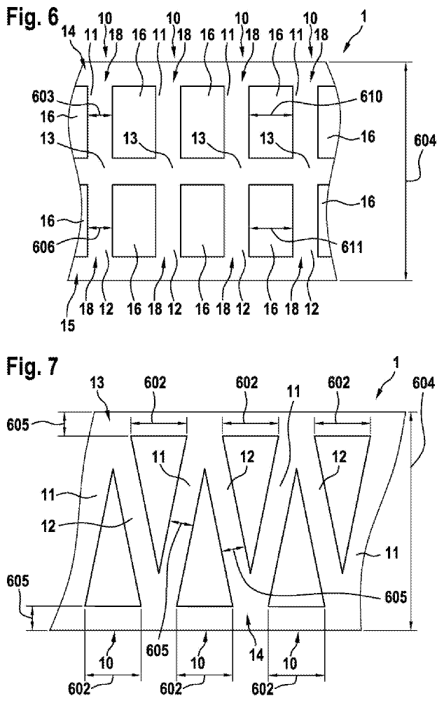

FIG. 7 shows a cooling fin 1 according to a sixth exemplary embodiment of the present invention.

Here, the cooling fin 1 comprises a periodically repeating profile 10, which is a V-shaped profile. Preferably, the cooling fin 1 is produced by means of an extrusion process.

The repeating V-shaped profile comprises a first bar 11 and a second bar 12, which are arranged relative to each other such that the profile 10 features a V-shape. The cooling fin 1 therefore comprises a plurality of first bars 11 and second bars 12.

Furthermore, the cooling fin 1 additionally comprises a third bar 13 and a fourth bar 14. The third bar 13 and the fourth bar 14 extend in the repeating direction 501 and are arranged relative to the first bars 11 and the second bars 12 such that triangular passage channels 16 are formed in the cooling fin 1.

A clear dimension 602 between adjacent bars 11, 12 in the repeating direction 501 corresponds to a maximum dimension of the corresponding passage channel 16 formed, and measures between 0.6 mm and 1.2 mm, preferably between 0.85 mm and 0.95 mm.

A height 604 of the cooling fin 1 measures between 5 mm and 8 mm, preferably between 5.9 mm and 6.1 mm.

Furthermore, a material thickness 605 of the cooling fin 1 can measure between 0.3 mm and 0.6 mm, preferably between 0.35 mm and 0.45 mm. The material thickness 605 of the cooling fin 1 in this case corresponds to a profile thickness of the repeating corrugated profile or a material thickness of the bars 11 to 14.

The cooling fin 1 according to the sixth exemplary embodiment of the invention can replace the cooling fin 1 according to the first exemplary embodiment. Furthermore, it is possible that the third bar 14 forms the first metal part 101 and the fourth bar 14 forms the second metal part 102 of the housing 100 in FIG. 1, in whole or in part.

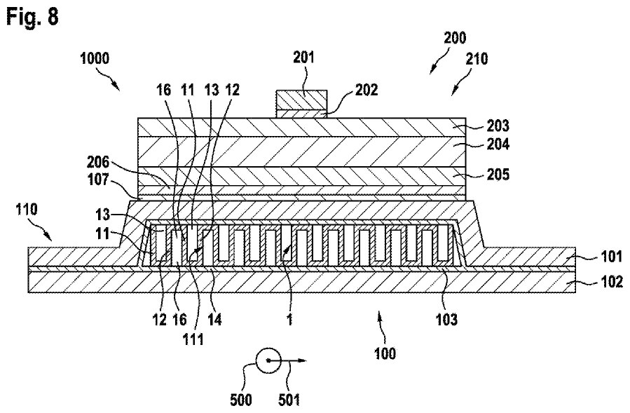

FIG. 8 shows a power electronics assembly 1000 according to a seventh exemplary embodiment of the present invention.

The power electronics assembly 1000 according to the seventh exemplary embodiment differs from that according to the first exemplary embodiment in that the first metal part 101, which is the upper part and thus faces the power electronics unit 210, comprises a plate-shaped region and a trapezoidal region in cross-section, whereby the second metal part 102, which is the lower part and thus faces the power electronics unit 210, is plate-shaped.

This design of the housing 110 can be advantageous in the event of a lack of space in the immediate vicinity of the power electronics unit 210.

It should be noted that the housing 110 of the cooler 100 according to the seventh exemplary embodiment can also be combined with a cooling fin 1 according to one of the exemplary embodiments two to six.

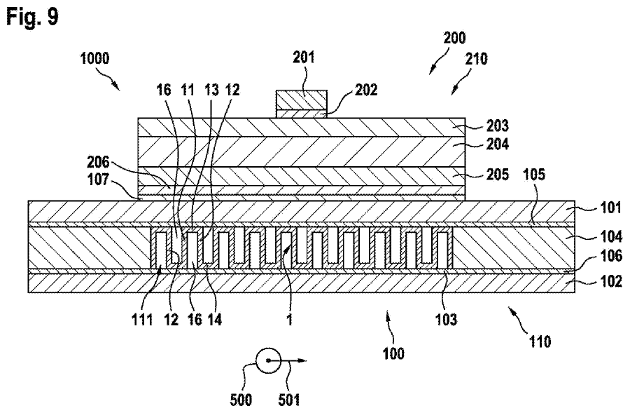

FIG. 9 refers to a power electronics assembly 1000 according to an eighth exemplary embodiment of the present invention.

Similar to the power electronics assembly 1000 according to the seventh exemplary embodiment, the power electronics assembly 1000 according to the eighth exemplary embodiment differs from that according to the first exemplary embodiment in the design of the housing 110 of the cooler 100.

As can be seen from FIG. 9, a third metal part 104 is provided in addition to the first metal part 101 and the second metal part 102, which together with the first metal part 101 and the second metal part 102 form the housing 110 of the cooler 100. The third metal part 104, which in particular is also designed as an aluminum part, is arranged between the first metal part 101 and the second metal part 102. The first metal part 101 is joined to the third metal part 104 by means of a first layer 105, which is connected to the second metal part 102 by means of a second layer 106. The first layer 105 and/or the second layer 106 is/are preferably each designed as a brazing solder layer.

It is understood that the cooling channel 111 is defined by the first metal part 101, the second metal part 102, and the third metal part 104.

This design of the housing 110 offers the advantage that it can be manufactured very easily.

It should be noted that the housing 110 of the cooler 100 according to the eighth exemplary embodiment can also be combined with a cooling fin 1 according to one of the exemplary embodiments two to six. If the cooling fins 1 in FIG. 6 or 7 are used, the first metal part 101 and the second metal part 102 can in this case also be replaced by the corresponding bars of the cooling fins.

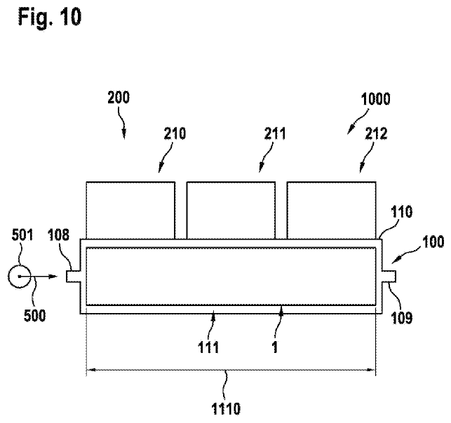

FIG. 10 shows a power electronics assembly 1000 according to a ninth exemplary embodiment of the present invention.

The power electronics 200 of the power electronics assembly 1000 according to the ninth exemplary embodiment comprises a first power electronics unit 210, a second power electronics unit 211 and a third power electronics unit 212.

In the flow direction, or rather the main flow direction, of the fluid used as coolant, the first power electronics unit 210 is arranged upstream of the second power electronics unit 211, which in turn is arranged upstream of the third power electronics unit 212 in the flow direction 500. The flow direction advantageously corresponds to a direction from an inlet 108 to an outlet 109 of the cooler 100.

The cooling fin 1 is associated with all power electronics units 210, 211, 212. In other words, heat generated by the power electronics units 210, 211, 212 during their operation is transferred to the single cooling fin 1 and from there to the fluid flowing through it. For this purpose, the cooling fin 1 extends in its extending direction 500 over an entire length 1110 of the cooling channel 111 of the cooler 100.

1. A cooling fin (1) of a cooler, (100) through which fluid can flow, for cooling power electronics (200), the cooling fin comprising a profile (10) periodically repeating in a repeating direction, wherein the repeating direction (501) is perpendicular to an extending direction (500) of the profile (10).

2. The cooling fin (1) according to claim 1, wherein the profile (10) repeats an integer or non-integer number of times.

3. The cooling fin (1) according to claim 1, wherein the periodically repeating profile (10) is a corrugated profile.

4. The cooling fin (1) according to claim 3, wherein a division (601) of the cooling fin (1) measures between 1.8 mm and 2.5 mm.

5. The cooling fin (1) according to claim 1, wherein the periodically repeating profile (10) is a cross-shaped profile which comprises a first bar (11), a second bar (12), and a third bar (13), wherein the first bar (11) and the second bar (12) are each situated at a perpendicular angle to the third bar (13) and protrude from the third bar (13).

6. The cooling fin (1) according to claim 5, wherein the cooling fin (1) further comprises a fourth bar (14), which extends parallel to the third bar (13) and is connected to an end region (18) of each first bar (11) or each second bar (12), or wherein the cooling fin (1) further comprises a fourth bar (14) and a fifth bar (15), which extend parallel to the third bar (13), wherein the fourth bar (14) is connected to an end region (18) of each first bar (11), and the fifth bar (15) is connected to an end region (18) of each second bar (12).

7. The cooling fin (1) according to claim 5, wherein a dimension of the first bar (11) in the repeating direction (501) of the cooling fin (1) is greater than a dimension of the second bar (12) in the repeating direction (501).

8. The cooling fin (1) according to claim 1, wherein the periodically repeating profile (10) is a V-shaped profile comprising a first bar (11) and a second bar (12).

9. The cooling fin (1) according to claim 1, wherein a height (604) of the cooling fin (1) measures between 5 mm and 8 mm, and/or
a material thickness (605; 603, 606) of the cooling fin (1) measures between 0.3 mm and 0.6 mm, and/or
a clear dimension (602; 610; 611) between adjacent bars (11, 12) of the cooling fin (1) in the repeating direction (501) measures between 0.6 mm and 1.2 mm.

10. A cooler (100) through which fluid can flow, for cooling power electronics (200), the cooler comprising a cooling fin (1) according to claim 1.

11. A cooler (100) through which fluid can flow according to claim 10, wherein a region (14, 15; 13, 14) of the cooling fin (1) corresponds to a part (101, 102) of a housing (110) of the cooler (100).

12. A power electronics assembly (1000) comprising power electronics (200) and a cooler (100) through which fluid can flow according to claim 10, wherein the power electronics (200) is arranged on the cooler (100).

13. The cooling fin (1) according to claim 3, wherein the cooling fin (1) is meander-shaped.

14. The cooling fin (1) according to claim 4, wherein the division (601) of the cooling fin (1) measures between 1.9 mm and 2.1 mm.

15. The cooling fin (1) according to claim 6, wherein a dimension of the first bar (11) in the repeating direction (501) of the cooling fin (1) is greater than a dimension of the second bar (12) in the repeating direction (501).

16. The cooling fin (1) according to claim 8, wherein:
the cooling fin (1) further comprises a third bar (13), wherein the third bar (13) extends in the repeating direction (501) and is arranged such that a triangular passage channel (16) is formed for each repetition of the profile (10) by the first bar (11), the second bar (12), and the third bar (13), or
the cooling fin (1) further comprises a third bar (13) and a fourth bar (14), wherein the third bar (13) and the fourth bar (14) extend in the repeating direction (501) and are arranged such that triangular passage channels (16) are formed in the cooling fin (1).

17. The cooling fin (1) according to claim 9, wherein the height (604) of the cooling fin (1) measures between 5.9 mm and 6.1 mm, and/or
the material thickness (605; 603, 606) of the cooling fin (1) measures between 0.35 mm and 0.45 mm, and/or
the clear dimension (602; 610; 611) between adjacent bars (11, 12) of the cooling fin (1) in the repeating direction (501) measures between 0.85 mm and 0.95 mm.

18. The cooler (100) according to claim 10, wherein the cooler (100) comprises a cooling channel (111) and exactly one cooling fin (1), which fin is arranged in the cooling channel (111), and a length (607) of the cooling fin (1) in the extending direction (500) is equal to a dimension (1110) of the cooling channel (111) in the extending direction (500).

19. The power electronics assembly (1000) according to claim 12, wherein the power electronics (200) is fixed on the cooler (100).
